(19) United States
(12) Patent Application Publication
(10) Pub. No.: US 2008/0180783 A1
(43) Pub. Date: Jul. 31, 2008

(54) Critical dimension control for photolithography for microelectromechanical systems devices

(76) Inventors: Li-Ming Wang, Hsinchu (TW); Wen-Sheng Chan, Jhubei City (TW)

Correspondence Address: KNOBBE MARTENS OLSON & BEAR LLP, 2040 MAIN STREET, FOURTEENTH FLOOR, IRVINE, CA, 92614, US

(21) Appl. No.: 11/657,844

(22) Filed: Jan. 25, 2007

(51) Int. Cl. G02B 26/00; G03F 7/30

(52) U.S. Cl. 359/291; 430/314

(57) ABSTRACT

A method of making a microelectromechanical system (MEMS) device is disclosed. The method includes forming a stationary layer and a moving layer spaced from the stationary layer. The method also includes forming at least one support structure configured to support the moving layer. Forming the at least one support structure includes forming a photoresist layer over the stationary layer and patterning the photoresist layer. Patterning the photoresist layer includes exposing the photoresist layer to light through a photomask. Then, the photoresist layer is first developed with a first developing solution for a first predetermined period of time after exposing. The first developing solution is removed after first developing. Subsequently, the photoresist layer is developed a second time with a second developing solution for a second predetermined period of time after removing the first developing solution. The second developing solution is removed after the second developing process.

### BACKGROUND OF THE INVENTION

1. Field of the Invention

This invention relates to microelectromechanical systems (MEMS) devices and methods for making the same. More particularly, this invention relates to a photolithographic process for making MEMS devices.

2. Description of the Related Art

Microelectromechanical systems (MEMS) include micro mechanical elements, actuators, and electronics. Micromechanical elements may be created using deposition, etching, and or other micromachining processes that etch away parts of substrates and/or deposited material layers or that add layers to form electrical and electromechanical devices. One type of MEMS device is called an interferometric modulator. As used herein, the term interferometric modulator or interferometric light modulator refers to a device that selectively absorbs and/or reflects light using the principles of optical interference. In certain embodiments, an interferometric modulator may comprise a pair of conductive plates, one or both of which may be transparent and/or reflective in whole or part and capable of relative motion upon application of an appropriate electrical signal. In a particular embodiment, one plate may comprise a stationary layer deposited on a substrate and the other plate may comprise a metallic membrane separated from the stationary layer by an air gap. As described herein in more detail, the position of one plate in relation to another can change the optical interference of light incident on the interferometric modulator. Such devices have a wide range of applications, and it would be beneficial in the art to utilize and/or modify the characteristics of these types of devices so that their features can be exploited in improving existing products and creating new products that have not yet been developed.

### SUMMARY OF THE INVENTION

In one aspect, a method of making a microelectromechanical system (MEMS) device is provided. The method includes forming a stationary layer. A moving layer is formed to be spaced from the stationary layer. At least one support structure is formed to support the moving layer. In forming the at least one support structure, a photoresist layer is formed over the stationary layer. Then, the photoresist layer is patterned. In patterning the photoresist layer, the photoresist layer is exposed to light through a photomask. The photoresist layer is first developed with a first developing solution for a first predetermined period of time after exposing. The first developing solution is removed after first developing. The photoresist layer is developed a second time with a second developing solution for a second predetermined period of time after removing the first developing solution. The second developing solution is removed after developing the photoresist layer the second time.

In another aspect, a microelectromechanical system (MEMS) comprising an array of MEMS devices is provided. Each of the devices includes a stationary layer and a moving layer overlying the stationary layer with a cavity therebetween. The moving layer is movable in the cavity between a first position and a second position. The first position is a first distance from the stationary layer. The second position is a second distance from the stationary layer. The second distance is greater than the first distance. Each of the devices further includes a support structure configured to support the moving layer. Each of the support structures across the array has a lateral dimension having a standard deviation from about ±0.01 μm to about ±0.45 μm.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIGS. 5A and 5B illustrate one exemplary timing diagram for row and column signals that may be used to write a frame of display data to the 3×3 interferometric modulator display of FIG. 2.

FIGS. 6A and 6B are system block diagrams illustrating an embodiment of a visual display device comprising a plurality of interferometric modulators.

FIG. 7A is a cross section of the device of FIG. 1.

FIG. 7B is a cross section of an alternative embodiment of an interferometric modulator.

FIG. 7C is a cross section of another alternative embodiment of an interferometric modulator.

FIG. 7D is a cross section of yet another alternative embodiment of an interferometric modulator.

FIG. 7E is a cross section of an additional alternative embodiment of an interferometric modulator.

FIGS. 8A-8N are schematic cross sections illustrating a method of making an interferometric modulator having support structures according to one embodiment.

FIG. 9 is a flow chart illustrating a method of developing a photoresist layer according to one embodiment.

FIGS. 10A-10C are schematic perspective views illustrating steps of the method of FIG. 9.

FIG. 11A is a micrograph, taken with a scanning electron microscope at a tilted angle, of an array of interferometric modulators according to one embodiment.

FIG. 11B is a micrograph, taken with a scanning electron microscope, of a partial cross-section of the array of FIG. 11A, showing a post structure.

FIGS. 12A-12L are schematic cross sections illustrating a method of making an interferometric modulator having support structures according to another embodiment.

### DETAILED DESCRIPTION OF THE PREFERRED EMBODIMENT

The following detailed description is directed to certain specific embodiments of the invention. However, the invention can be embodied in a multitude of different ways. In this description, reference is made to the drawings wherein like parts are designated with like numerals throughout. As will be apparent from the following description, the embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

In fabricating a microelectromechanical systems (MEMS) device, a photolithographic process may be employed to form various elements of the MEMS device, and particularly for defining lateral dimensions of supports for interferometric devices. During a photolithographic process, a photoresist is exposed to light and is developed using a developing solution. A photolithographic process according to one embodiment includes a multiple development process to improve critical dimension uniformity of elements. The multiple development process includes repeating steps of dispensing a developing solution over a photoresist layer and removing the solution from over the layer.

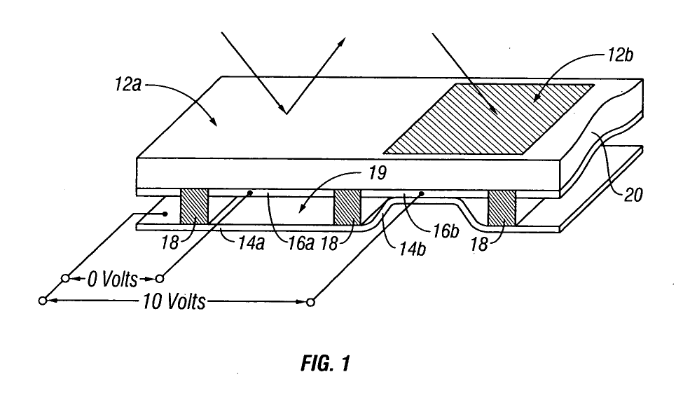

One interferometric modulator display embodiment comprising an interferometric MEMS display element is illustrated in FIG. 1. In these devices, the pixels are in either a bright or dark state. In the bright (“on” or “open”) state, the display element reflects a large portion of incident visible light to a user. When in the dark (“off” or “closed”) state, the display element reflects little incident visible light to the user. Depending on the embodiment, the light reflectance properties of the “on” and “off” states may be reversed. MEMS pixels can be configured to reflect predominantly at selected colors, allowing for a color display in addition to black and white.

FIG. 1 is an isometric view depicting two adjacent pixels in a series of pixels of a visual display, wherein each pixel comprises a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical cavity with at least one variable dimension. In one embodiment, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically comprise of several fused layers, which can include an electrode layer, such as indium tin oxide (ITO), a partially reflective layer, such as chromium, and a transparent dielectric. The optical stack 16 is thus electrically conductive, partially transparent and partially reflective, and may be fabricated, for example, by depositing one or more of the above layers onto a transparent substrate 20. In some embodiments, the layers are patterned into parallel strips, and may form row electrodes in a display device as described further below. The movable reflective layers 14a, 14b may be formed as a series of parallel strips of a deposited metallic layer or layers (orthogonal to the row electrodes of 16a, 16b) deposited on top of posts 18 and an intervening sacrificial material deposited between the posts 18. When the sacrificial material is etched away, the movable reflective layers 14a, 14b are separated from the optical stacks 16a, 16b by a defined gap or cavity 19. A highly conductive and reflective material such as aluminum may be used for the reflective layers 14, and these strips may form column electrodes in a display device.

With no applied voltage, the cavity 19 remains between the movable reflective layer 14a and optical stack 16a, with the movable reflective layer 14a in a mechanically relaxed state, as illustrated by the pixel 12a in FIG. 1. However, when a potential difference is applied to a selected row and column, the capacitor formed at the intersection of the row and column electrodes at the corresponding pixel becomes charged, and electrostatic forces pull the electrodes together. If the voltage is high enough, the movable reflective layer 14 is deformed and is forced against the optical stack 16. A dielectric layer (not illustrated in this Figure) within the optical stack 16 may prevent shorting and control the separation distance between layers 14 and 16, as illustrated by pixel 12b on the right in FIG. 1. The behavior is the same regardless of the polarity of the applied potential difference. In this way, row/column actuation that can control the reflective vs. non-reflective pixel states is analogous in many ways to that used in conventional LCD and other display technologies.

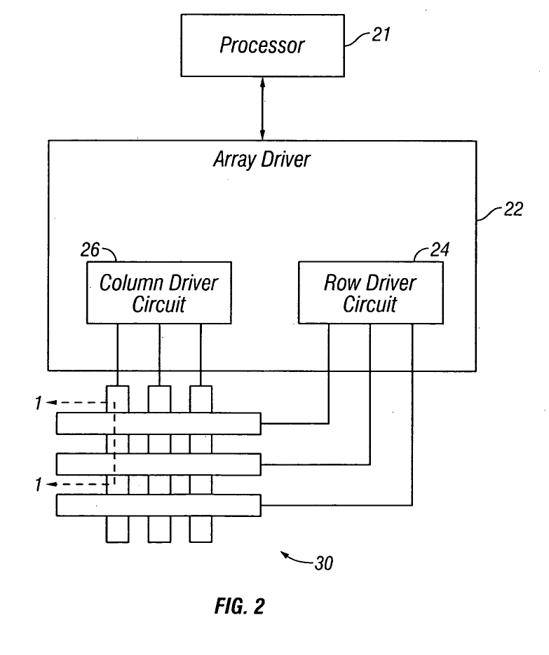

FIGS. 2 through 5 illustrate one exemplary process and system for using an array of interferometric modulators in a display application.

FIG. 2 is a system block diagram illustrating one embodiment of an electronic device that may incorporate aspects of the invention. In the exemplary embodiment, the electronic device includes a processor 21 which may be any general purpose single- or multi-chip microprocessor such as an ARM, Pentium®, Pentium II®, Pentium III®, Pentium IV®, Pentium® Pro, an 8051, a MIPS®, a Power PC®, an ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

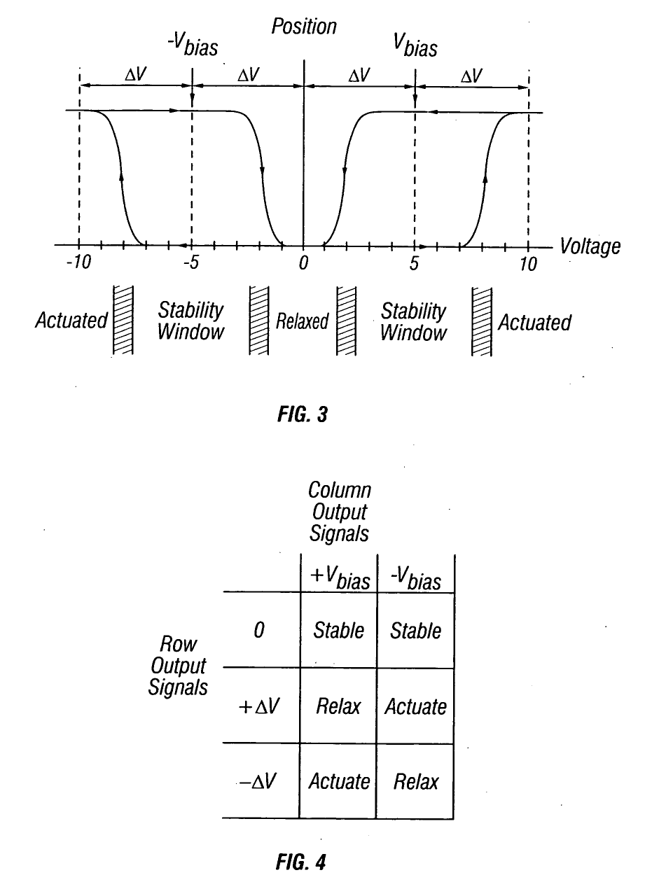

In one embodiment, the processor 21 is also configured to communicate with an array driver 22. In one embodiment, the array driver 22 includes a row driver circuit 24 and a column driver circuit 26 that provide signals to a panel or display array (display) 30. The cross section of the array illustrated in FIG. 1 is shown by the lines 1-1 in FIG. 2. For MEMS interferometric modulators, the row/column actuation protocol may take advantage of a hysteresis property of these devices illustrated in FIG. 3. It may require, for example, a 10 volt potential difference to cause a movable layer to deform from the relaxed state to the actuated state. However, when the voltage is reduced from that value, the movable layer maintains its state as the voltage drops back below 10 volts. In the exemplary embodiment of FIG. 3, the movable layer does not relax completely until the voltage drops below 2 volts. There is thus a range of voltage, about 3 to 7 V in the example illustrated in FIG. 3, where there exists a window of applied voltage within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a voltage within the hysteresis window with almost no power dissipation. Essentially no current flows into the pixel if the applied potential is fixed.

In typical applications, a display frame may be created by asserting the set of column electrodes in accordance with the desired set of actuated pixels in the first row. A row pulse is then applied to the row 1 electrode, actuating the pixels corresponding to the asserted column lines. The asserted set of column electrodes is then changed to correspond to the desired set of actuated pixels in the second row. A pulse is then applied to the row 2 electrode, actuating the appropriate pixels in row 2 in accordance with the asserted column electrodes. The row 1 pixels are unaffected by the row 2 pulse, and remain in the state they were set to during the row 1 pulse. This may be repeated for the entire series of rows in a sequential fashion to produce the frame. Generally, the frames are refreshed and/or updated with new display data by continually repeating this process at some desired number of frames per second. A wide variety of protocols for driving row and column electrodes of pixel arrays to produce display frames are also well known and may be used in conjunction with the present invention.

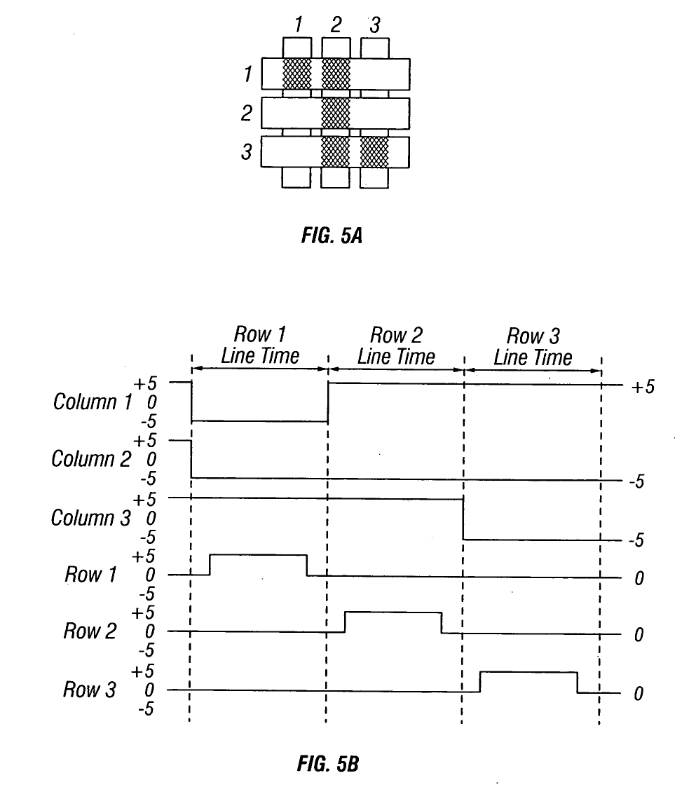

FIGS. 4 and 5 illustrate one possible actuation protocol for creating a display frame on the 3×3 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5 volts and +5 volts respectively Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, it will be appreciated that voltages of opposite polarity than those described above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are at 0 volts, and all the columns are at +5 volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. It will be appreciated that the same procedure can be employed for arrays of dozens or hundreds of rows and columns. It will also be appreciated that the timing, sequence, and levels of voltages used to perform row and column actuation can be varied widely within the general principles outlined above, and the above example is exemplary only, and any actuation voltage method can be used with the systems and methods described herein.

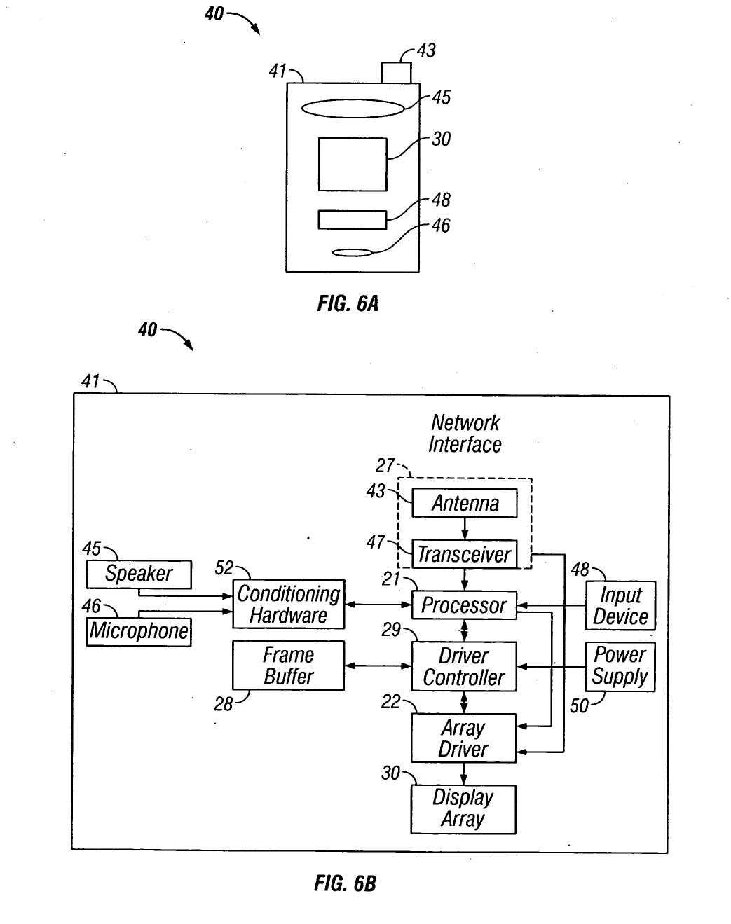

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions and portable media players.

The display device 40 includes a housing 41, a display 30, an antenna 43, a speaker 45, an input device 48, and a microphone 46. The housing 41 is generally formed from any of a variety of manufacturing processes as are well known to those of skill in the art, including injection molding, and vacuum forming. In addition, the housing 41 may be made from any of a variety of materials, including but not limited to plastic, metal, glass, rubber, and ceramic, or a combination thereof. In one embodiment the housing 41 includes removable portions (not shown) that may be interchanged with other removable portions of different color, or containing different logos, pictures, or symbols.

The display 30 of exemplary display device 40 may be any of a variety of displays, including a bi-stable display, as described herein. In other embodiments, the display 30 includes a flat-panel display, such as plasma, EL, OLED, STN LCD, or TFT LCD as described above, or a non-flat-panel display, such as a CRT or other tube device, as is well known to those of skill in the art. However, for purposes of describing the present embodiment, the display 30 includes an interferometric modulator display, as described herein.

The components of one embodiment of exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43 which is coupled to a transceiver 47. The transceiver 47 is connected to the processor 21, which is connected to conditioning hardware 52. The conditioning hardware 52 may be configured to condition a signal (e.g. filter a signal). The conditioning hardware 52 is connected to a speaker 45 and a microphone 46. The processor 21 is also connected to an input device 48 and a driver controller 29. The driver controller 29 is coupled to a frame buffer 28 and to the array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one or more devices over a network. In one embodiment the network interface 27 may also have some processing capabilities to relieve requirements of the processor 21. The antenna 43 is any antenna known to those of skill in the art for transmitting and receiving signals. In one embodiment, the antenna transmits and receives RF signals according to the IEEE 802.11 standard, including IEEE 802.11(a), (b), or (g). In another embodiment, the antenna transmits and receives RF signals according to the BLUETOOTH standard. In the case of a cellular telephone, the antenna is designed to receive CDMA, GSM, AMPS or other known signals that are used to communicate within a wireless cell phone network. The transceiver 47 pre-processes the signals received from the antenna 43 so that they may be received by and further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a digital video disc (DVD) or a hard-disc drive that contains image data, or a software module that generates image data.

The processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to the frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. The conditioning hardware 52 generally includes amplifiers and filters for transmitting signals to the speaker 45, and for receiving signals from the microphone 46. The conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and reformats the raw image data appropriately for high speed transmission to the array driver 22. Specifically, the driver controller 29 reformats the raw image data into a data flow having a raster-like format, such that it has a time order suitable for scanning across the display array 30. Then the driver controller 29 sends the formatted information to the array driver 22. Although a driver controller 29, such as a LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and reformats the video data into a parallel set of waveforms that are applied many times per second to the hundreds and sometimes thousands of leads coming from the display's x-y matrix of pixels.

In one embodiment, the driver controller 29, array driver 22, and display array 30 are appropriate for any of the types of displays described herein. For example, in one embodiment, the driver controller 29 is a conventional display controller or a bi-stable display controller (e.g., an interferometric modulator controller). In another embodiment, the array driver 22 is a conventional driver or a bi-stable display driver (e.g., an interferometric modulator display). In one embodiment, the driver controller 29 is integrated with the array driver 22. Such an embodiment is common in highly integrated systems such as cellular phones, watches, and other small area displays. In yet another embodiment, the display array 30 is a typical display array or a bi-stable display array (e.g., a display including an array of interferometric modulators).

The input device 48 allows a user to control the operation of the exemplary display device 40. In one embodiment, the input device 48 includes a keypad, such as a QWERTY keyboard or a telephone keypad, a button, a switch, a touch-sensitive screen, a pressure- or heat-sensitive membrane. In one embodiment, the microphone 46 is an input device for the exemplary display device 40. When the microphone 46 is used to input data to the device, voice commands may be provided by a user for controlling operations of the exemplary display device 40.

The power supply 50 can include a variety of energy storage devices as are well known in the art. For example, in one embodiment, the power supply 50 is a rechargeable battery, such as a nickel-cadmium battery or a lithium ion battery. In another embodiment, the power supply 50 is a renewable energy source, a capacitor, or a solar cell, including a plastic solar cell, and solar-cell paint. In another embodiment, the power supply 50 is configured to receive power from a wall outlet.

In some implementations control programmability resides, as described above, in a driver controller which can be located in several places in the electronic display system. In some cases control programmability resides in the array driver 22. Those of skill in the art will recognize that the above-described optimization may be implemented in any number of hardware and/or software components and in various configurations.

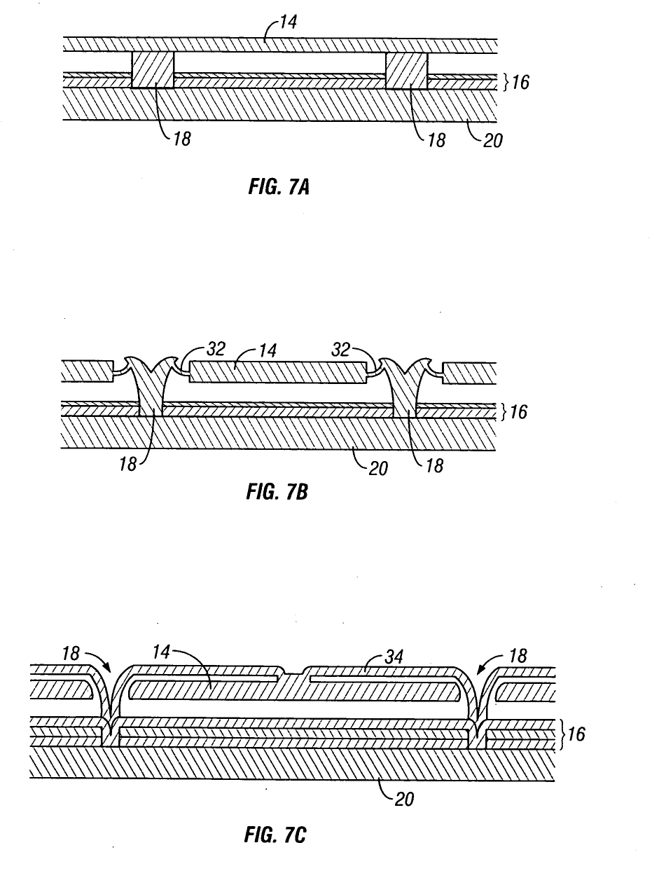

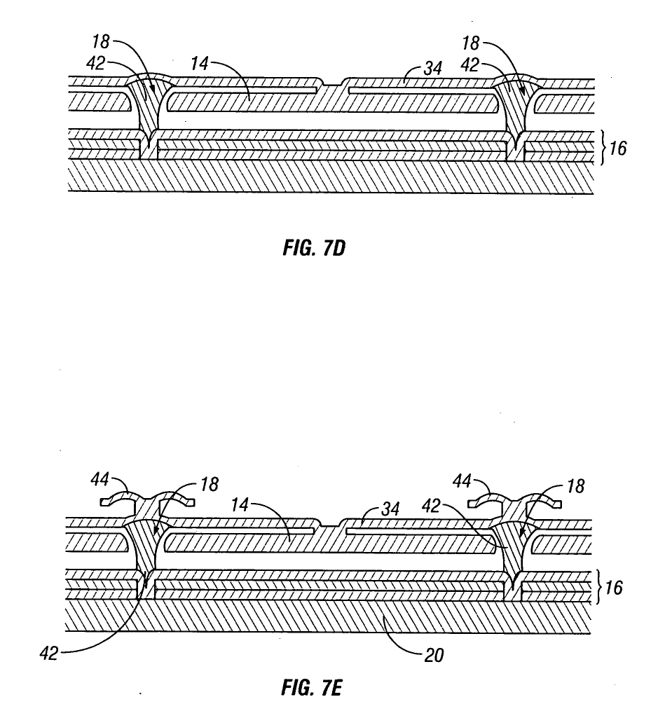

The details of the structure of interferometric modulators that operate in accordance with the principles set forth above may vary widely. For example, —FIGS. 7A-7E illustrate five different embodiments of the movable reflective layer 14 and its supporting structures. FIG. 7A is a cross section of the embodiment of FIG. 1, where a strip of metal material 14 is deposited on orthogonally extending supports 18. In FIG. 7B, the movable reflective layer 14 is attached to supports at the corners only, on tethers 32. In FIG. 7C, the movable reflective layer 14 is suspended from a deformable layer 34, which may comprise a flexible metal. The deformable layer 34 connects, directly or indirectly, to the substrate 20 at various locations. The connections are herein referred to as support structures or posts 18. The embodiment illustrated in FIG. 7D has support structures 18 including support post plugs 42 upon which the deformable layer 34 rests. The movable reflective layer 14 remains suspended over the cavity, as in FIGS. 7A-7C, but the deformable layer 34 does not form the support posts 18 by filling holes between the deformable layer 34 and the optical stack 16. Rather, the support posts 18 are formed of a planarization material, which is used to form support post plugs 42. The embodiment illustrated in FIG. 7E is based on the embodiment shown in FIG. 7D, but may also be adapted to work with any of the embodiments illustrated in FIGS. 7A-7C as well as additional embodiments not shown. In the embodiment shown in FIG. 7E, an extra layer of metal or other conductive material has been used to form a bus structure 44. This allows signal routing along the back of the interferometric modulators, eliminating a number of electrodes that may otherwise have had to be formed on the substrate 20.

In embodiments such as those shown in FIG. 7, the interferometric modulators function as direct-view devices, in which images are viewed from the front side of the transparent substrate 20, the side opposite to that upon which the movable electrode is arranged. In these embodiments, the reflective layer 14 optically shields some portions of the interferometric modulator on the side of the reflective layer opposite the substrate 20, including the deformable layer 34 and the bus structure 44. This allows the shielded areas to be configured and operated upon without negatively affecting the image quality. This separable modulator architecture allows the structural design and materials used for the electromechanical aspects and the optical aspects of the modulator to be selected and to function independently of each other. Moreover, the embodiments shown in FIGS. 7C-7E have additional benefits deriving from the decoupling of the optical properties of the reflective layer 14 from its mechanical properties, which are carried out by the deformable layer 34. This allows the structural design and materials used for the reflective layer 14 to be optimized with respect to the optical properties, and the structural design and materials used for the deformable layer 34 to be optimized with respect to desired mechanical properties.

### Multiple Photoresist Development Process

In fabricating a microelectromechanical systems (MEMS) device, a photolithographic process may be employed to form various elements of the MEMS device. Examples of such elements include, but are not limited to, support structures and electrodes (fixed and moving electrodes).

The support structures include, for example, posts and rivets. The term, “posts,” as used herein, generally refers to a support structure underlying a mechanical layer in a MEMS device to lend mechanical support for the mechanical layer. As used herein, the term “rivet” generally refers to a patterned layer overlying a mechanical layer in a MEMS device, usually in a recess or depression in a post or support region, to lend mechanical support for the mechanical layer.

Preferably, though not always, the posts may include wings extending laterally from the posts to add stability and predictability to the mechanical layer's movement. Similar to the posts, the rivets may also include wings overlying an upper surface of the mechanical layer. In many of the embodiments herein, the preferred materials for the posts and rivets are inorganic for stability relative to organic photoresist materials.

It will be recognized that vertical dimensions of the support structures (e.g., posts, rivets, or wings of the foregoing) are critical to defining a gap between fixed and moving electrodes. In an optical MEMS device (e.g., an interferometric modulator), the dimensions of the support structures are critical in generating a desired color from a pixel. The inventors have realized that lateral dimensions of support structures can also be critical to control over the gap in a MEMS device.

In forming the support structures, a photolithographic process may be conducted as follows. A material for a support structure is first deposited over a substrate. In one embodiment, a positive photoresist layer is formed over a layer of the material for the support structure. Subsequently, the photoresist layer is exposed to light through a photomask. Next, exposed portions of the photoresist layer are selectively removed using a developing solution. As a result, the positive photoresist layer includes openings corresponding to those of the photomask. Then, the material for the support structure is selectively etched using the photoresist as a mask, thereby forming the desired support structure. In another embodiment, a negative photoresist layer may be used for patterning support structures. In such an embodiment, unexposed portions of the photoresist layer are removed while exposed portions thereof remain and serve as a mask for patterning the support structures.

The process of selectively removing portions of a photoresist layer is generally referred to as “development.” In a typical development process, a developing solution is dispensed over a photoresist and is maintained for a predetermined period of time. Then, the development is completed by removing the developing solution from over the photoresist.

A photolithographic process according to one embodiment includes a multiple development process as opposed to the typical single development process described above. The photoresist layer is first developed with a first developing solution for a first predetermined period of time. Then, the first developing solution is removed after first developing. Subsequently, the photoresist layer is developed again with a second developing solution for a second predetermined period of time. Then, the second developing solution is removed after the second developing process. The development may be repeated such that it is conducted two or more times, preferably, 2 to 5 times, more preferably 2 to 3 times.

The multiple development process achieves critical dimension uniformity of support structures described above. For example, critical dimension variation of support structures may be controlled within a range of about ±0.1 μm, as compared to about ±0.5 μm using the same lithography system but only one development step.

Although embodiments in this disclosure are illustrated in the context of forming support structures, the multiple development process may apply to forming other elements (e.g., electrodes) of a MEMS device. In addition, embodiments in this disclosure are illustrated in the context of optical MEMS devices, particularly interferometric modulators. The skilled artisan will, however, appreciate that the multiple development process described above may apply to other MEMS devices, such as electromechanical capacitive switches.

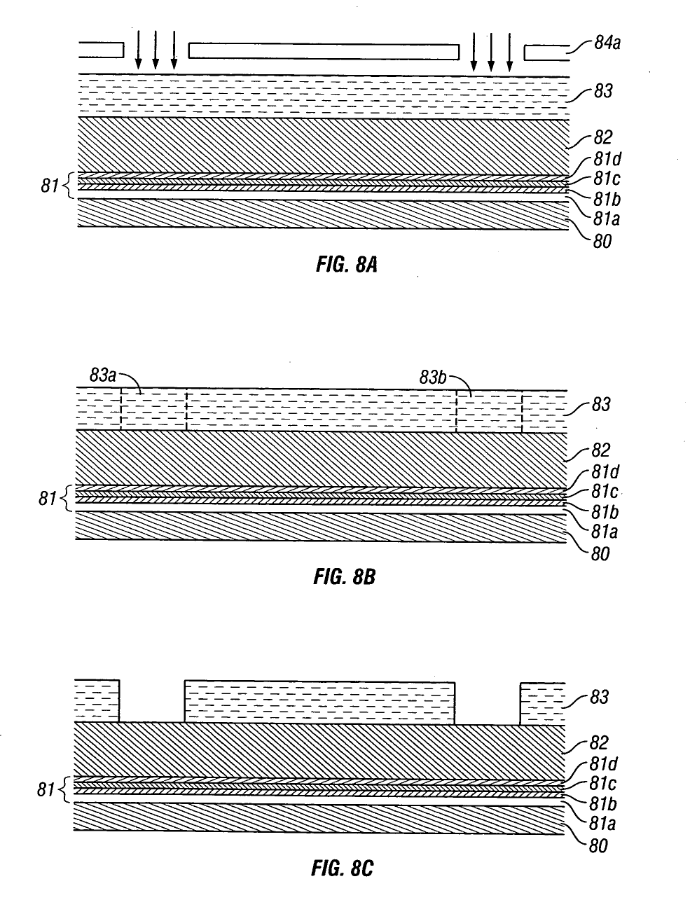

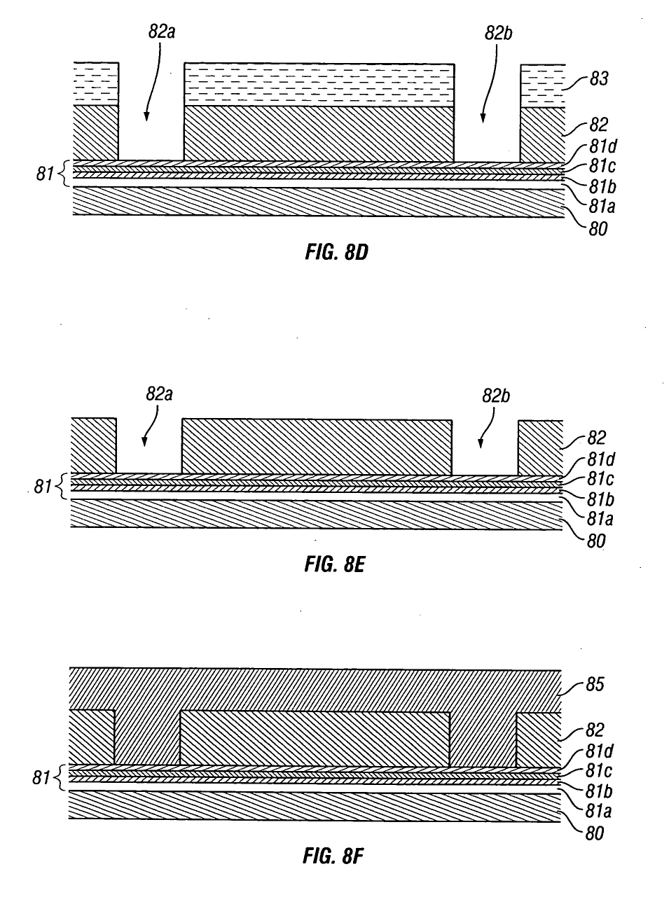

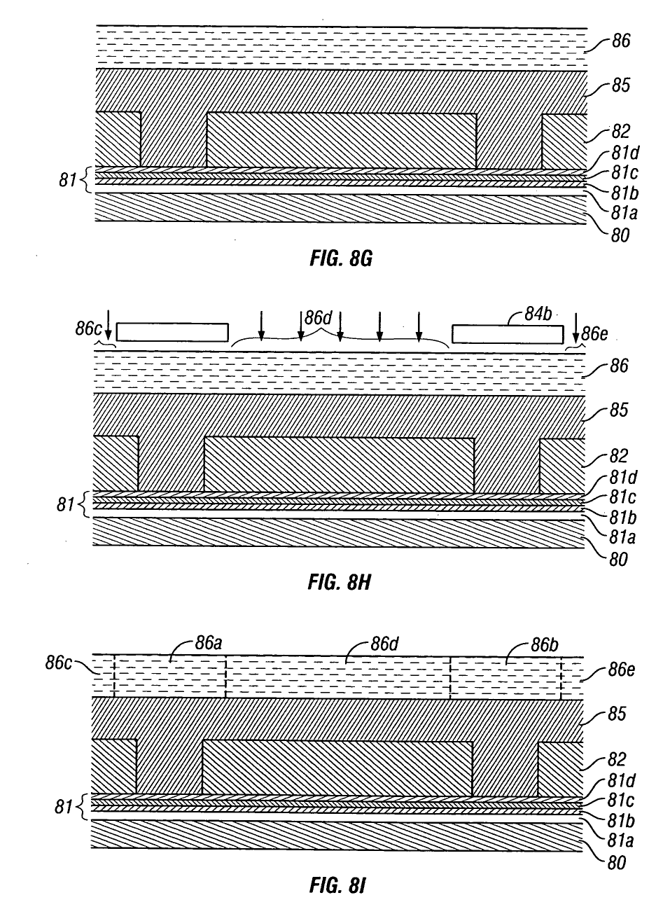

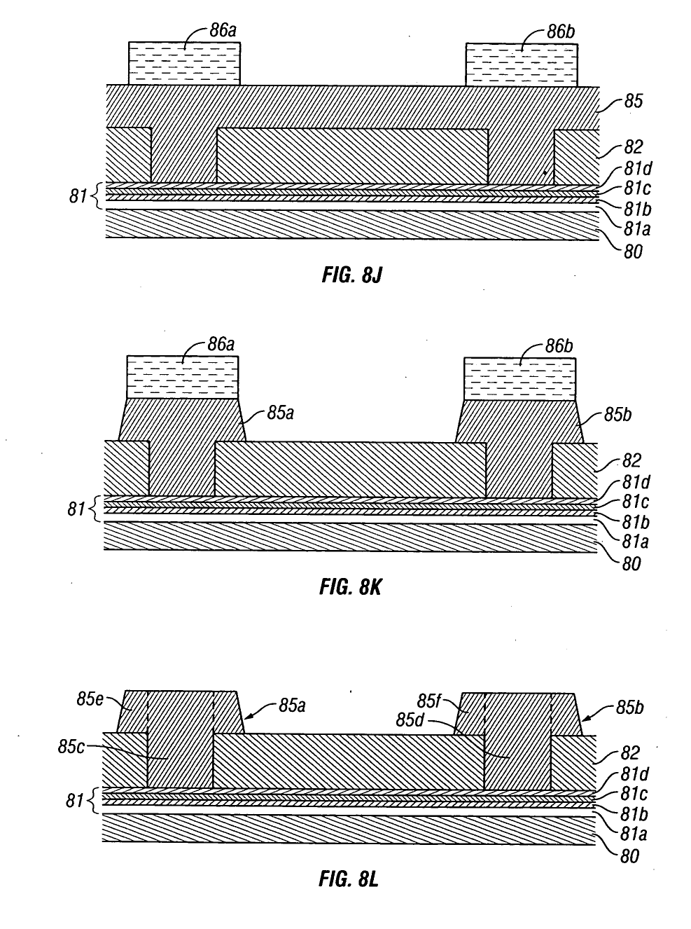

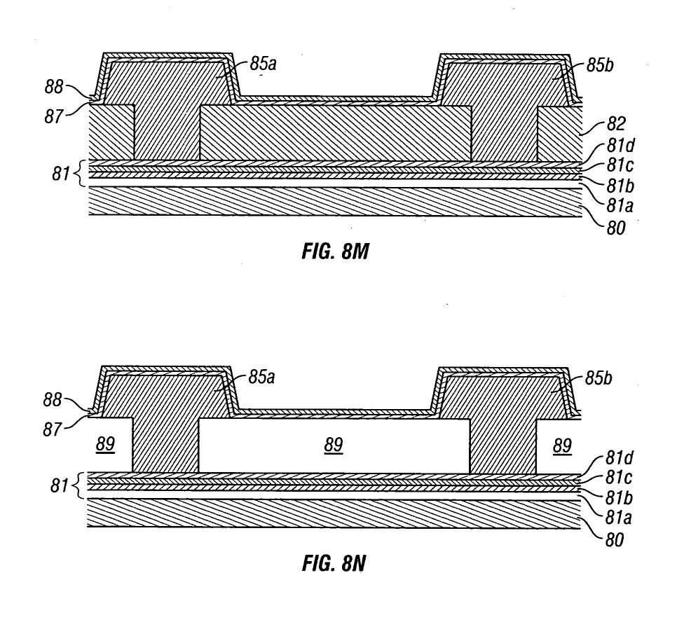

FIGS. 8A-8N illustrate a method of making an interferometric modulator according to an embodiment. In the illustrated method, posts with post wings are formed using the multiple development process.

In FIG. 8A, an optical stack 81 is provided over a transparent substrate 80. In the illustrated embodiment, the optical stack 81 has a transparent conductor in the form of an ITO layer 81a overlying the substrate 80, a metallic absorber layer 81b overlying the ITO layer 81a, a first dielectric layer 81c overlying the absorber layer 81b, and a second dielectric layer 81d overlying the first dielectric layer 81c. The absorber layer 81b is preferably formed of chromium. In another embodiment for a broad-band white interferometric modulator, the absorber layer 81b may be formed of a semiconductor layer. The semiconductor layer is preferably formed of germanium. The first dielectric layer 81c may be formed of silicon dioxide. The second dielectric layer 81d may be formed of aluminum oxide and may serve as an etch stop layer during a release etch of a sacrificial layer, as will be better appreciated from the description of FIG. 8N. In certain embodiments, either or both of the dielectric layers 81c and 81d may be omitted.

In one embodiment, the ITO layer 81a may have a thickness between about 100 Å and about 800 Å. The absorber layer 81b may have a semitransparent thickness, preferably between about 1 Å and about 50 Å, more preferably between about 10 Å and about 40 Å. The overall thickness of the first and second dielectric layers 81c and 81d may be between about 100 Å and about 1,600 Å. In other embodiments, the thicknesses of the dielectric layers 81c and 81d may be adjusted such that the fixed electrode 81 is a color filter. In a process not shown here, the ITO layer 81a and the absorber layer 81b are patterned and etched to form electrode lines or other useful shapes as required by the display design. Current convention refers to the lower electrode lines as row electrodes.

Subsequently, a sacrificial layer 82 is formed over the optical stack 81, as shown in FIG. 8A. The sacrificial layer 82 is preferably formed of a material capable of selective removal without harm to other materials that define the cavity. In the illustrated embodiment, the sacrificial layer 82 is formed of molybdenum. Other examples of sacrificial materials that can be selectively removed by fluorine-containing etchants include silicon and tungsten.

Next, steps for forming posts are performed. A photolithographic process is performed to pattern the sacrificial layer 82 to provide recesses for posts. A photoresist layer 83 is provided over the sacrificial layer 82. The photoresist layer 83 may be formed of any suitable photoresist including, but not limited to, AZ 501 (available from Clariant Corporation, Somerville, N.J., U.S.A.) and ECA4 (available from EC Co. Ltd., Taoyuan, Taiwan). The illustrated photoresist layer 83 for the examples provided herein, is formed of a positive photoresist. The photoresist layer 83 may have a thickness between about 1 μm and about 7 μm. A skilled artisan will appreciate that a negative photoresist can also be used for patterning the sacrificial layer 82, in which case unexposed resist will be removed.

Subsequently, a photomask 84a (also referred to as a reticle) is provided over the photoresist layer 83. The photomask 84a is for a positive photoresist and includes openings for light to reach portions of the photoresist layer 83 which are to be removed. Then, light is irradiated through the photomask 84a onto exposed portions of the photoresist layer 83. This step of irradiating light may be generally referred to as an “exposure step.” The light is selected from various wavelengths depending on the material for the photoresist layer 83. Examples of irradiating light include, but are not limited to, ultraviolet (UV) of various wavelengths and visible light. The exposed portions 83a, 83b of the photoresist layer 83 undergo wavelength-specific radiation-sensitive chemical reactions, preferably a reaction that changes an acidity of the exposed portions. In the illustrated embodiment, the chemical reactions cause the exposed portions 83a, 83b to be more acidic, as shown in FIG. 8B. In another embodiment where a negative photoresist is used, exposed portions of a photoresist layer become less acidic. In certain embodiments, a photoresist may include polymeric compounds which undergo a cross-linking reaction upon exposure to light. In the context of this document, such a photoresist may be referred to as a “cross-linking photoresist.” In such embodiments, the polymeric compounds are cross-linked upon exposure to light, thereby hardening the exposed portions of the photoresist.

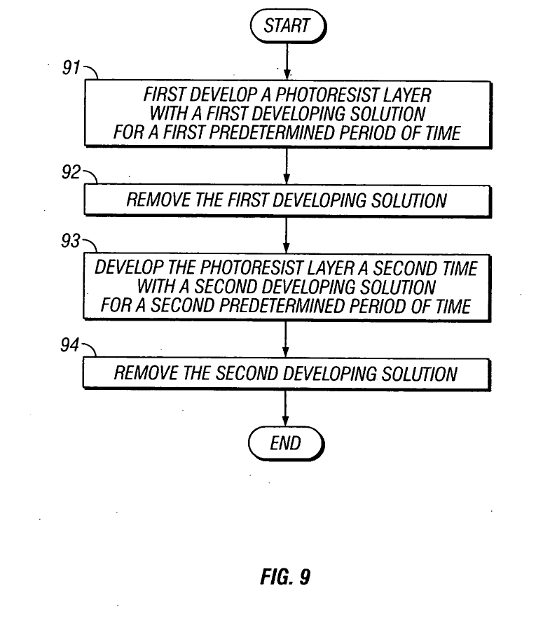

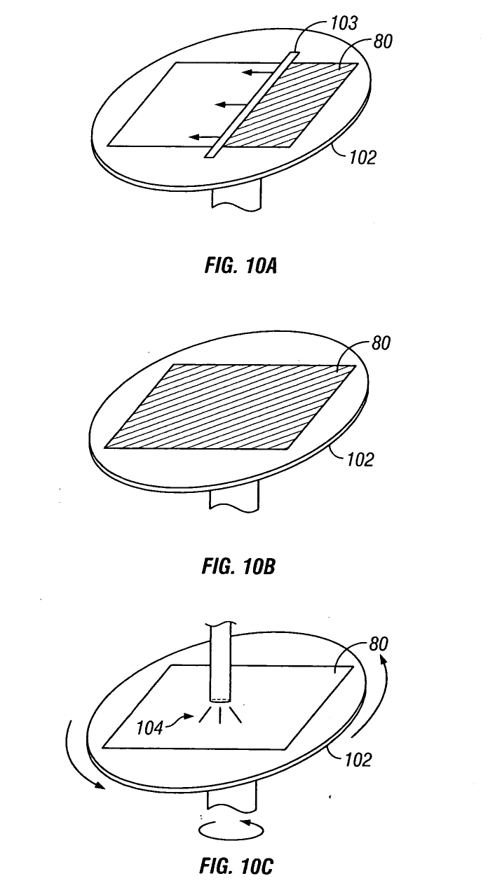

Subsequently, a multiple development process is performed to remove the exposed portions 83a, 83b of the photoresist layer 83. Referring to FIGS. 9 and 10, the multiple development process is described below. In step 91, the photoresist layer is first developed with a first developing solution for a first predetermined period of time. The first developing solution may be any developing solution suitable for developing the photoresist. Examples of the developing solution include, but are not limited to, tetramethylammonium hydroxide (TMAH) and KOH. The developing solution may have a concentration of about 1% to about 10% TMAH or KOH in deionized (DI) water. It will be appreciated that the developing solution will remove unexposed portions of a photoresist layer if the layer is formed of a negative photoresist or a cross-linking photoresist.

FIGS. 10A and 10B illustrates one embodiment of the step 91. First, the substrate 80 having the optical stack, the sacrificial layer, and the photoresist layer formed thereon is placed on a holder 102. Then, the first developing solution is dispensed over the substrate 80 using a moving dispenser 103. The illustrated moving dispenser 103 moves from one end of the substrate 80 to the other. It will be appreciated that various methods of dispensing the developing solution are possible. FIG. 10B illustrates the substrate 80 after the first developing solution has been applied over the surface of the substrate 80.

Next, the first developing solution is maintained on the substrate 80 for the first predetermined period of time. In the illustrated embodiment, the first predetermined period of time is preferably shorter than developing time required for the typical single development process described above. For example, if the developing time of the single development process is about 90 seconds, the first predetermined period of time may be about 20 seconds under the same conditions (e.g., using the same composition and concentration of developing solution) as those of the single development process. In other embodiments, the first predetermined period of time may range between about 5 seconds and about 40 seconds, preferably between about 10 seconds and about 30 seconds. A skilled artisan will appreciate that the first predetermined period of time may vary widely depending on the composition of the developing solution, the type and thickness of the photoresist, and other developing conditions such as temperature.

After the first predetermined period of time has elapsed, the first developing solution is removed, as shown in step 92 of FIG. 9. Referring to FIG. 10C, in one embodiment for the step 92, deionized (DI) water 104 is provided over the substrate 80 while spinning the holder 102 so as to wash away the developing solution from over the substrate 80. Then, the substrate 80 is spin-dried by spinning the holder 102 at a higher rotating speed. The rotating speed may be between about 500 rpm and about 1600 rpm.

Referring back to FIG. 9, in step 93, the photoresist layer is developed a second time with a second developing solution for a second predetermined period of time. The second developing solution may be any developing solution suitable for developing the photoresist. The second developing solution may have the same composition and concentration as the first developing solution. Alternatively, the second developing solution may have a different composition and/or concentration from the first developing solution.

Details of the step 93 may be as described above with respect to those of the step 91 except for the second predetermined period of time. Similar to the first predetermined period of time, in the illustrated embodiment, the second predetermined period of time is preferably shorter than the developing time required for the typical single development process described above. For example, if the developing time of the single development process is about 90 seconds, the second predetermined period of time may be about 65 seconds under the same conditions (e.g., using the same composition and concentration of developing solution) as those of the single development process.

In one embodiment, the second predetermined period of time is longer than the first predetermined period of time. The second predetermined period of time may be from about 60% to about 90% of a total of the first and second predetermined periods of time. In other embodiments, the second predetermined period of time may range between about 20 seconds and about 90 seconds, preferably between about 40 seconds and about 70 seconds. A skilled artisan will appreciate that the second predetermined period of time may vary widely depending on the composition and concentration of the developing solution, the type and thickness of the photoresist, and other developing conditions such as temperature.

After the second predetermined period of time has elapsed, the second developing solution is removed, as shown in step 94 of FIG. 9. Details of the step 94 may be as described above with respect to those of the step 92.

In an unpictured embodiment, an additional developing step similar to those described above may be conducted. For example, the photoresist layer may be developed a third time with a third developing solution for a third predetermined period of time. In another embodiment, the photoresist layer may be further developed with a fourth developing solution for a fourth predetermined period of time. It will be appreciated that the third and fourth predetermined periods of time may be selected based on the composition and concentration of the developing solution, the type and thickness of the photoresist, and other developing conditions such as temperature. It will also be appreciated that additional developing steps may be conducted after the fourth developing process. FIG. 8C illustrates the photoresist layer 83 with the exposed portions 83a, 83b (FIG. 8B) removed.

Then, the sacrificial layer 82 is etched using a dry etch process, preferably using a fluorine-based etchant such as SF₆/O₂, CF₄/O₂, or NF₃, or a chlorine-based etchant such as Cl₂/BCl₃, as shown in FIG. 8D. In another embodiment, the sacrificial layer 82 may be etched using a wet etch process, preferably using an etchant such as H₂SO₄/HNO₃/H₂O, H₃PO₄/CH₃COOH/HNO₃ or HCl/H₂O₂. In the illustrated embodiment, the sacrificial layer 82 has holes 82a, 82b having vertical sidewalls. In other embodiments, the sacrificial layer may have holes having sloped sidewalls for easier subsequent deposition into the holes.

The photoresist layer is then stripped, as shown in FIG. 8E, and the substrate may be optionally cleaned and descummed. Subsequently, a material 85 for the posts, preferably an inorganic dielectric material such as silicon dioxide, is deposited over exposed surfaces, including surfaces of the sacrificial layer 82, as shown in FIG. 8F.

Subsequently, steps for patterning post wings are carried out, as shown in FIGS. 8G-8L. As shown in FIG. 8G, another photoresist layer 86 (a positive photoresist in the illustrated embodiment) is formed over the layer 85 of the material for the posts. Then, another photomask 84b (FIG. 8H) is provided over the photoresist layer 86. The illustrated photomask 84b is for a positive photoresist and includes openings for light to reach portions of the photoresist layer 86 which are to be removed. Post wings will be defined by selectively removing portions of the layer 85 of the post material from over the sacrificial layer 82, as will be better understood from the description below.

Then, light is irradiated through the photomask 84b to define exposed portions 86c, 86d, 86e (FIG. 8I) of the photoresist layer 86. This exposure step may be as described above with respect to the exposure step shown in FIG. 8A. Upon exposure to light, the exposed portions 86c, 86d, 86e of the photoresist layer 86 become more acidic than unexposed portions 86a, 86b. In another embodiment where a negative photoresist is used, portions of the photoresist to be removed are masked while other portions are exposed to light. In certain embodiments, the photoresist may include polymeric compounds which can be cross-linked upon exposure to light. In such embodiments, the polymeric compounds in the exposed portions of the photoresist layer are cross-linked to one another upon exposure to light, thereby hardening the exposed portions.

Subsequently, a multiple development process is performed to remove the exposed portions 86c, 86d, 86e of the photoresist layer 86. Details of the multiple development process is as described above with reference to FIGS. 9 and 10. FIG. 8J illustrates unexposed portions 86a, 86b of the photoresist layer 86 which remain after the multiple development process.

Then, the material for the posts is etched using the unexposed portions 86a, 86b as a mask. The material for the posts may be etched, using a suitable etch process, including a wet or dry etch process, as shown in FIG. 8K. Subsequently, the unexposed portions 86a, 86b of the photoresist layer are stripped, as shown in FIG. 8L. The remaining portions of the post material form posts 85a, 85b. In FIG. 8L, each of the posts 85a, 85b includes a post stem 85c, 85d filling the holes of the sacrificial layer 82. In addition, each of the posts 85a, 85b includes a post wing 85e, 85f extending from over the post stem 85c, 85d and partially overlying the sacrificial layer 82. The post wings 85e, 85f are annular when viewed from the top. It will be appreciated that the post wings 85e, 85f are optional, and may be omitted.

Next, a reflective layer 87 is deposited over the sacrificial layer 82 and over the posts 85a, 85b (including the post wings), as shown in FIG. 8M. The reflective layer 87 is preferably formed of a specular metal such as Al, Au, Ag, or an alloy of the foregoing. In certain embodiments where the MEMS device is used as an electromechanical capacitive switch, the layer 87 may be formed of a conductor such as Cu, Pt, Ni, Au, Al, or an alloy of the foregoing.

Then, a material for a mechanical or deformable layer 88 is deposited over the reflective layer 87, as shown in FIG. 8M. The material for the deformable layer 88 is preferably nickel. Then, the aluminum and nickel layers 87 and 88 are patterned and etched to define an array of interferometric modulators. In certain embodiments, the deformable layer 88 and the reflective layer 87 are etched to provide through-holes (not shown). The etch process can be either a wet or dry etch process. The holes serve to permit etchant to enter and etch byproduct to exit at a release step which will be described below. In addition, the holes provide an exit for air when the reflective layer 87 moves between the relaxed and actuated positions. FIG. 8M illustrates a cross-section of a completed “unreleased” interferometric modulator structure with the sacrificial layer 82 in place.

In an unpictured embodiment, after a sacrificial layer is formed on an optical stack, a reflective layer is formed and patterned thereon. Subsequently, another sacrificial layer is deposited over the reflective layer. Then, the sacrificial layers are patterned to provide recesses for posts, and the posts are formed in the recesses. Subsequently, a deformable layer is formed over the second sacrificial layer and the posts. This process provides a deformable layer from which the reflective layer can be suspended, as described above with reference to FIGS. 7C-7E. In addition, different steps may be performed to form electrode structures having options such as a tethered moving electrode, as shown in FIG. 7B. Although not illustrated, a skilled artisan will appreciate that the multiple development process described above may apply to forming elements, and particularly support elements, of the interferometric modulators of FIGS. 7A-7E.

Finally, the sacrificial layer 82 is selectively removed, leaving a cavity or gap 89 between the reflective layer 87 and the optical stack 81, as shown in FIG. 8N. This step is referred to as a “release” or “sacrificial etch” step. The illustrated sacrificial layer 82, which is formed of molybdenum, is preferably etched using a fluorine-based etchant, for example, a XeF₂-based etchant, which selectively etches molybdenum without attacking other exposed materials (SiO₂, Al₂O₃, Al, etc.) that define the cavity 89. A resulting “released” MEMS device, particularly interferometric modulator, is shown in FIG. 8N. Although not illustrated, a skilled artisan will appreciate that different steps may be performed to form electrode structures having options such as tethered or suspended moving electrode, as shown in FIGS. 7B-7E.

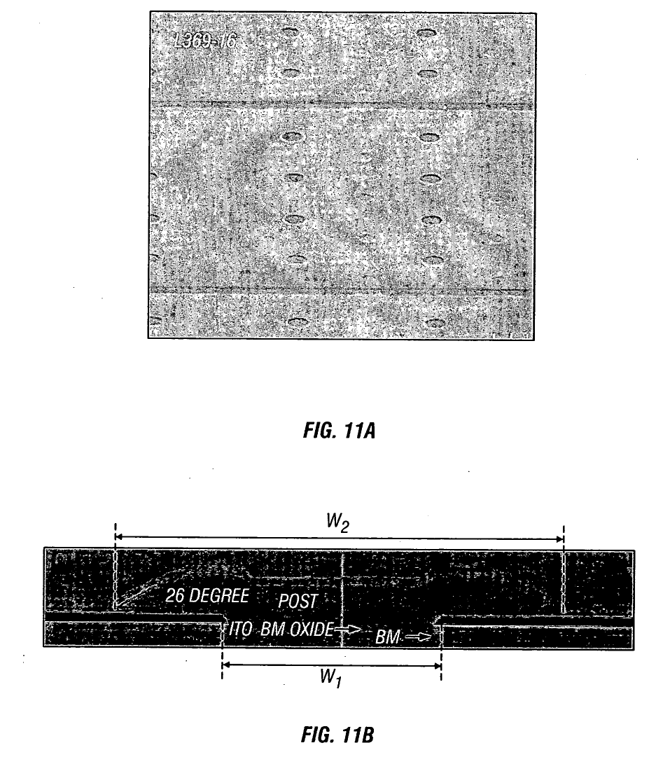

FIG. 11A is a micrograph, taken with a scanning electron microscope at a tilted angle, of an array of interferometric modulators according to one embodiment. FIG. 11A shows oval-shaped posts spread across the array of interferometric modulators. Because the micrograph of FIG. 11A was taken at a tilted angle, the posts are actually substantially circular when viewed from the top.

FIG. 11B is a micrograph, taken with a scanning electron microscope, of a partial cross-section of the array of interferometric modulators of FIG. 11A. FIG. 11B shows an optical stack (the horizontal lines below the discontinuous horizontal black strips) over a substrate (the lowermost horizontal strip), a post (the portion in the center between the two discontinuous black strips and the portion extending laterally from over the portion in the center), a reflective/mechanical layer (the line extending over the post wing and the black strips), and cavities (the discontinuous black horizontal strips) between the optical stack and the reflective/mechanical layer on both sides of the post.

In FIG. 11B, the portion in the center between the two discontinuous black strips may be referred to as a “post stem,” in the context of this document. The post stem shown in FIG. 11B is tapered downward, and thus has different horizontal widths at different vertical levels. The post stem has a maximum horizontal width W₁ (hereinafter, referred to as a “width W₁”). Each of the posts of FIG. 11A has a post stem as shown in FIG. 11B. The post stems of the posts across the array have widths W₁ (or lateral dimensions) with a standard deviation from about ±0.01 μm to about ±0.45 μm. Each of the post stems across the array has a width W₁ (or lateral dimension) having a maximum deviation from about 0.01 μm to about 0.5 μm.

The portions extending laterally from over the post stem and partially overlying the cavities form a post wing. The post wing is oval-shaped when viewed from the top, as shown in FIG. 11A. The post wing shown in FIG. 11B has a cross-section with sloped side ends, and thus has different horizontal widths at different vertical levels. The post wing has a maximum horizontal width W₂ (hereinafter, referred to as a “width W₂”). The post wings across the array have widths W₂ (or lateral dimensions) with a standard deviation from about ±0.01 μm to about ±0.45 μm. Each of the post wings across the array has a width W₂ (or lateral dimension) having a maximum deviation from about 0.01 μm to about 0.5 μm.

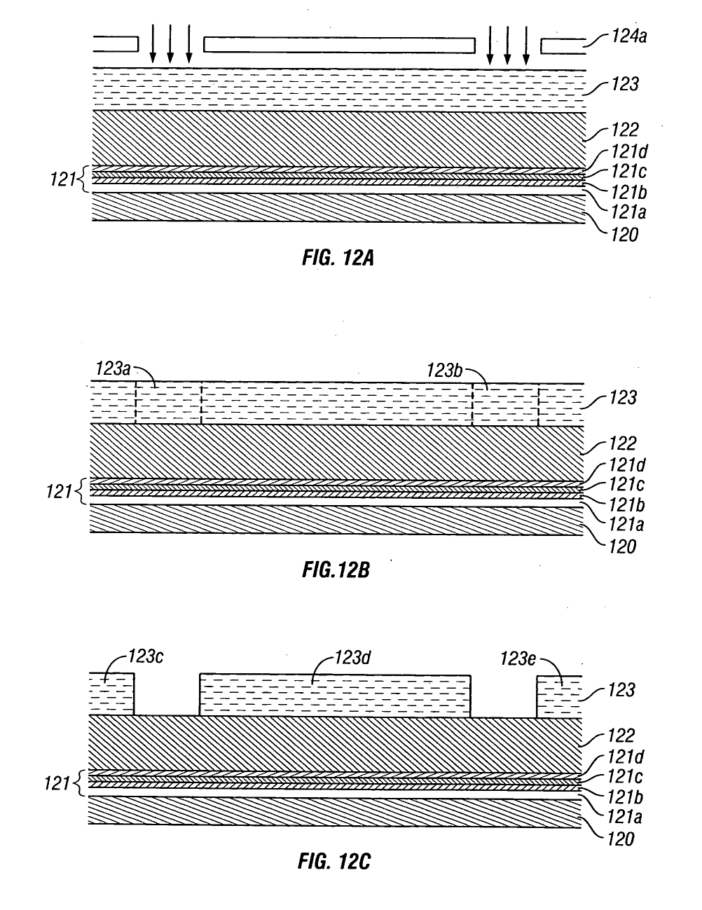

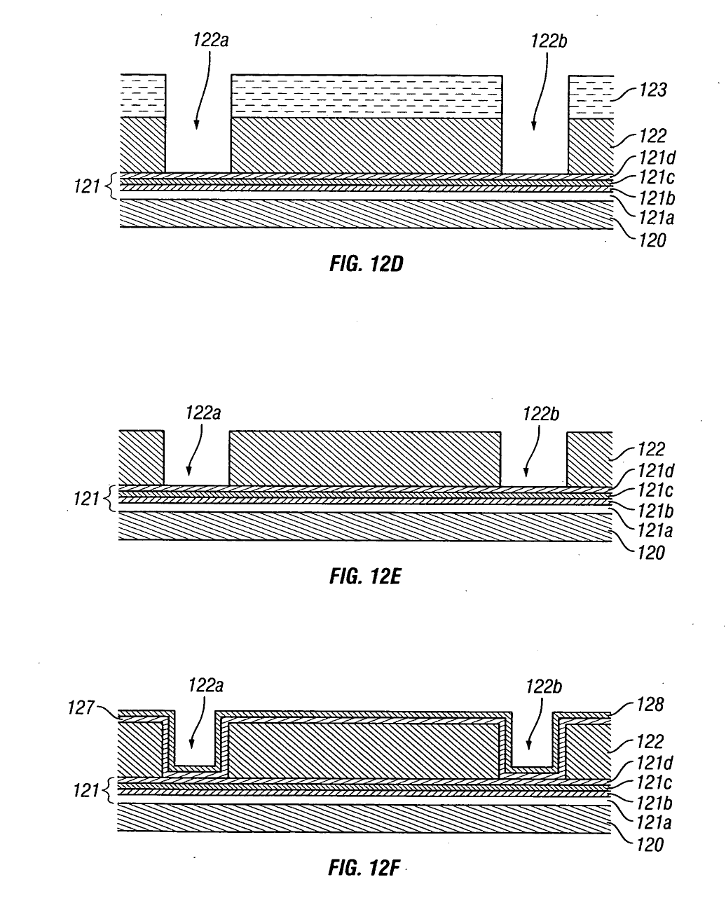

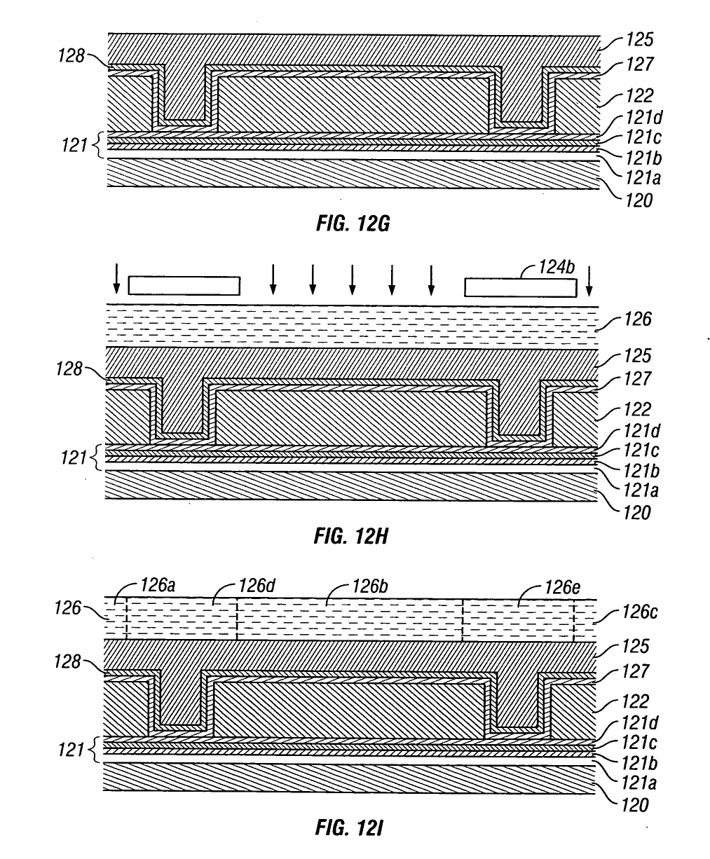

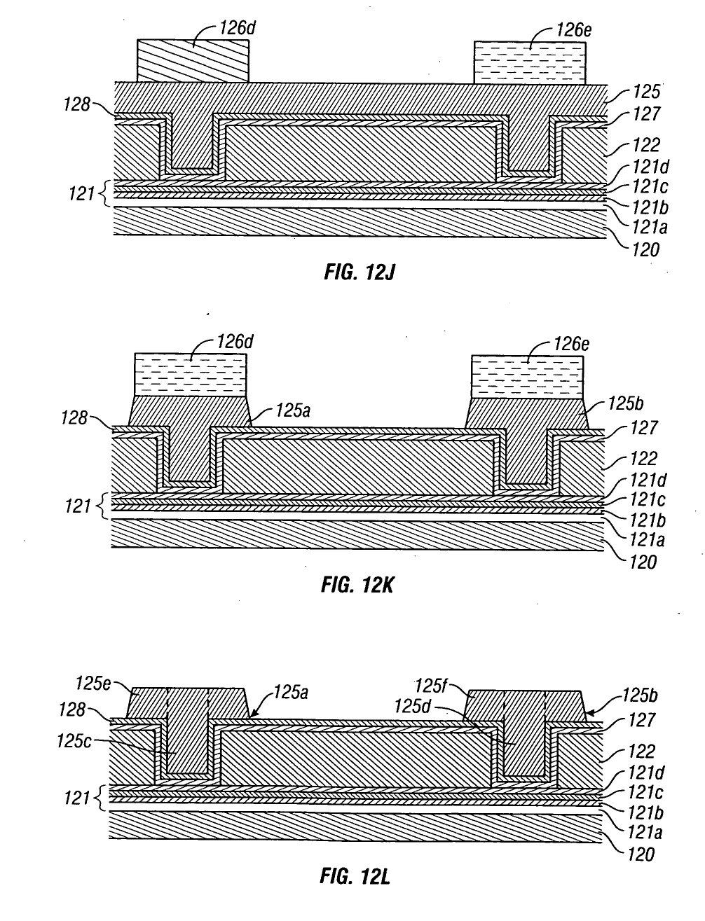

FIGS. 12A-12L illustrate a method of making an interferometric modulator having support structures according to another embodiment. In the illustrated method, rivets including rivet wings are formed using the multiple development process.

In FIG. 12A, an optical stack 121 is provided over a transparent substrate 120. In the illustrated embodiment, the optical stack 121 has a transparent conductor in the form of an ITO layer 121a overlying the substrate 120, a metallic absorber layer 121b overlying the ITO layer 121a, a first dielectric layer 121c overlying the absorber layer 121b, and a second dielectric layer 121d overlying the first dielectric layer 121c. The absorber layer 121b is preferably formed of chromium. In another embodiment for a broad-band white interferometric modulator, the absorber layer 121b may be formed of a semiconductor layer. The semiconductor layer is preferably formed of germanium. The first dielectric layer 121c may be formed of silicon dioxide. The second dielectric layer 121d may be formed of aluminum oxide and may serve as an etch stop layer during a release etch of a sacrificial layer. In certain embodiments, either or both of the dielectric layers 121c and 121d may be omitted. The layers 121a-121d may have thicknesses the same as those of the layers 81a-81d described above with reference to FIG. 8A. In a process not shown here, the ITO layer 121a and the absorber layer 121b are patterned and etched to form electrode lines (“row electrodes”) or other useful shapes as required by the display design.

Subsequently, a sacrificial layer 122 is formed over the optical stack 121, as shown in FIG. 12A. The sacrificial layer 122 is preferably formed of a material capable of selective removal without harm to other materials that define the cavity. In the illustrated embodiment, the sacrificial layer 122 is formed of molybdenum. Other examples of sacrificial materials that can be selectively removed by fluorine-based etchants include silicon and tungsten.

Next, steps for forming recesses for the rivets in the sacrificial layer 122 are performed. A photolithographic process is performed to pattern the sacrificial layer 122 to provide recesses or depressions for the rivets. A photoresist layer 123 is provided over the sacrificial layer 122. The photoresist layer 123 may be formed of any suitable photoresist including, but not limited to, AZ 501 (available from Clariant Corporation, Somerville, N.J., U.S.A.) and ECA4 (available from EC Co. Ltd., Taoyuan, Taiwan). The illustrated photoresist layer 123 is formed of a positive photoresist. The photoresist layer 123 may have a thickness between about 1 μm and about 7 μm. A skilled artisan will appreciate that a negative photoresist can also be used for patterning the sacrificial layer 122.

Subsequently, a photomask 124a is provided over the photoresist layer 123. The photomask 124a is for a positive photoresist and includes openings for light to reach portions of the photoresist layer 123 which are to be removed. Then, light is irradiated through the photomask 124a onto exposed portions of the photoresist layer 123. Details of this step are as described above with respect to those of the exposure step, shown in FIG. 8A. The exposed portions 123a, 123b of the photoresist layer 123 become more acidic, as shown in FIG. 12B. In another embodiment where a negative photoresist is used, portions of a photoresist exposed to light becomes less acidic. In yet another embodiment where a cross-linking photoresist is used, portions of a photoresist exposed to light are hardened.

Subsequently, a multiple development process is performed to remove the exposed portions 123a, 123b of the photoresist layer 123. Details of the multiple development process are as described above with reference to FIGS. 9 and 10. FIG. 12C illustrates unexposed portions 123c, 123d, 123e of the photoresist layer which remain after the multiple development process.

Then, the sacrificial layer 122 is etched using a dry etch process, preferably using a fluorine-based etchant such as SF₆/O₂, CF₄/O₂, or NF₃, or a chlorine-based etchant such as Cl₂/BCl₃, as shown in FIG. 12D. In another embodiment, the sacrificial layer 122 may be etched using a wet etch process, preferably using an etchant such as H₂SO₄/HNO₃/H₂O, H₃PO₄/CH₃COOH/HNO₃ or HCl/H₂O₂. In the illustrated embodiment, the sacrificial layer 122 has recesses or depressions 122a, 122b having vertical sidewalls. In other embodiments, the sacrificial layer 122 may have recesses having sloped sidewalls for easier subsequent deposition into the recesses. The photoresist layer 123 is then stripped, as shown in FIG. 12E.

Next, a reflective layer 127 is conformally deposited over the sacrificial layer 122 and into the recesses or depressions 122a, 122b in the sacrificial layer 122, as shown in FIG. 12F. The reflective layer 127 is preferably formed of a specular metal, such as Al, Au, Ag, or an alloy of the foregoing. In certain embodiments where the MEMS device is used as an electromechanical capacitive switch, the layer 127 may be formed of a conductor such as Cu, Pt, Ni, Au, Al, or an alloy of the foregoing. Then, a material for a mechanical or deformable layer 128 is deposited over the reflective layer 127, as shown in FIG. 12F. The material for the deformable layer 128 is preferably nickel.

Then, the reflective and deformable layers 127 and 128 are patterned and etched to define an array of interferometric modulators. In certain embodiments, the deformable layer 128 and the reflective layer 127 are etched to provide through-holes (not shown). The etch process can be either a wet or dry etch process. The holes serve to permit etchant to enter and etch by-product to exit at a release step which will be described below. In addition, the holes provide an exit for air when the reflective layer 127 moves between the relaxed and actuated positions. Subsequently, a material for the rivets, preferably an inorganic dielectric material such as silicon dioxide, is deposited over exposed surfaces of the deformable layer 128, as shown in FIG. 12G.

Subsequently, steps for patterning the rivets, including the rivet wings, are carried out, as shown in FIGS. 12H-12L. As shown in FIG. 12G, another photoresist 126 layer (a positive photoresist in the illustrated embodiment) is formed over a layer 125 of the material for the rivets. Then, another photomask 124b (FIG. 12H) is provided over the photoresist layer 126. The photomask 124b is for a positive photoresist and includes openings allowing light to reach portions of the photoresist layer 126 which are to be removed. Then, light is irradiated through the photomask 124b to define exposed portions of the photoresist layer 126. Details of this exposure step may be as described above with reference to FIG. 8H. Upon exposure to light, the exposed portions 126a, 126b, 126c of the photoresist layer 126 become more acidic than unexposed portions 126d, 126e, as shown in FIG. 12I. In another embodiment where a negative photoresist is used, portions of the photoresist to be removed are masked while the other portions are exposed to light. In certain embodiments, the photoresist may include polymeric compounds which can be cross-linked upon exposure to light. In such embodiments, the polymeric compounds are cross-linked to one another upon exposure to light, thereby hardening the exposed portions.

Subsequently, a multiple development process is performed to remove the exposed portions 126a, 126b, 126c of the photoresist layer 126. Details of the multiple development process are as described above with reference to FIGS. 9 and 10. FIG. 12J illustrates the unexposed portions 126d, 126e of the photoresist layer which remain after the multiple development process.

Then, the material for the rivets is etched using the unexposed portions 126d, 126e as a mask. The material for the posts may be etched, using a suitable etch process, including a wet or dry etch process, as shown in FIG. 12K. Subsequently, the unexposed portions 126d, 126e of the photoresist layer are stripped, as shown in FIG. 12L. The remaining portions of the rivet material form rivets 125a, 125b. In FIG. 12L, each of the rivets 125a, 125b includes a rivet stem 125c, 125d positioned within the recesses or depressions and rivet wings 125e, 125f extending laterally from over the rivet stem 125c, 125d and partially overlying the sacrificial layer 122. The rivet wings 125e, 125f are annular when viewed from the top. It will be appreciated that the rivet wings 125e, 125f are optional, and may be omitted. A skilled artisan will appreciate that the multiple development process described above may apply to fabricating interferometric modulators having various configurations of rivets.

Finally, although not shown, the sacrificial layer 122 is selectively removed, leaving a cavity or gap between the reflective layer 127 and the optical stack 121. This “release” or “sacrificial etch” step may be as described above with reference to FIG. 8N. Although not illustrated, a skilled artisan will appreciate that different steps may be performed to form electrode structures having options such as tethered or suspended moving electrode, as shown in FIGS. 7B-7E.

The multiple development process described above achieves critical dimension (CD) uniformity of the support structures. For example, a critical dimension variation of resulting support structures may be controlled within a range of about ±0.1 μm. As noted above, these laterally defined dimensions can critically affect the vertical gap size and hence color of an interferometric modulator.

It should be noted that the multiple development process described above can be performed on a photoresist layer used to etch any material layer when forming an interferometric modulator or MEMS device. Such a material layer may be used to form a structure other than posts or rivets. Examples of the structure include, but are not limited to, an optical stack, a reflective layer, a movable layer, a mechanical or deformable layer, and a sacrificial layer.

It should also be noted that the embodiments described above are applicable to an interferometric modulator structure viewed from the opposite side, compared to that shown in FIG. 1. Such a configuration has a reflective electrode closer to the substrate (which need not be transparent) and a semitransparent electrode farther from the substrate. Either or both electrodes could be made movable. In addition, although not shown, it should be noted that the embodiments of FIG. 8-12 may be combined with options of the embodiments described above with reference to FIGS. 1-7.

The above-described modifications can lead to a more robust design and fabrication. Additionally, while the above aspects have been described in terms of selected embodiments of the interferometric modulator, one of skill in the art will appreciate that many different embodiments of interferometric modulators may benefit from the above aspects. Of course, as will be appreciated by one of skill in the art, additional alternative embodiments of the interferometric modulator can also be employed. The various layers of interferometric modulators can be made from a wide variety of conductive and non-conductive materials that are generally well known in the art of semi-conductor and electromechanical device fabrication. In addition, the embodiments, although described with respect to an interferometric modulator, are applicable more generally to other MEMS devices.

While the above detailed description has shown, described, and pointed out novel features of the invention as applied to various embodiments, it will be understood that various omissions, substitutions, and changes in the form and details of the device or process illustrated may be made by those skilled in the art without departing from the spirit of the invention. As will be recognized, the present invention may be embodied within a form that does not provide all of the features and benefits set forth herein, as some features may be used or practiced separately from others.

We claim:

1. A method of making a microelectromechanical system (MEMS) device, the method comprising:
forming a stationary layer;
forming a moving layer spaced from the stationary layer; and
forming at least one support structure configured to support the moving layer, wherein forming the at least one support structure comprises:
forming a photoresist layer over the stationary layer; and
patterning the photoresist layer, wherein patterning the photoresist layer comprises:
exposing the photoresist layer to light through a photomask;
first developing the photoresist layer with a first developing solution for a first predetermined period of time after exposing;
removing the first developing solution after first developing;
developing the photoresist layer a second time with a second developing solution for a second predetermined period of time after removing the first developing solution; and
removing the second developing solution after developing the photoresist layer the second time.

2. The method of claim 1, further comprising forming a sacrificial layer after forming the stationary layer and before forming the moving layer, wherein forming the at least one support structure comprises forming a hole in the sacrificial layer, and wherein the photoresist layer serves as a mask for forming the hole in the sacrificial layer.

3. The method of claim 2, wherein the sacrificial layer comprises a material selected from the group consisting of molybdenum, silicon, and tungsten.

4. The method of claim 2, wherein forming the at least one support structure further comprises filling the hole in the sacrificial layer with a support material, and wherein forming the moving layer comprises depositing a moving layer material over the sacrificial layer and the support material.

5. The method of claim 1, further comprising forming a sacrificial layer after forming the stationary layer and before forming the moving layer, wherein forming the at least one support structure comprises, in sequence:
forming a hole in the sacrificial layer;
overfilling the hole in the sacrificial layer with a support material; and
patterning the support material, thereby leaving a portion of the support material over the sacrificial layer, wherein the portion of the support material is wider than and overlapping with the hole, wherein the photoresist layer serves a mask for patterning the support material.

6. The method of claim 1, further comprising forming a sacrificial layer after forming the stationary layer and before forming the moving layer, wherein forming the at least one support structure comprises, in sequence:
forming a depression in the sacrificial layer, wherein the photoresist layer serves as a mask for forming the depression in the sacrificial layer;
depositing a moving layer material conformally over the sacrificial layer such that a portion of the moving layer material is in the depression; and
depositing a support material over the moving layer material such that at least a portion of the support material is formed over the portion of the moving layer material in the depression.

7. The method of claim 1, further comprising forming a sacrificial layer after forming the stationary layer and before forming the moving layer, wherein forming the at least one support structure comprises, in sequence:
forming a depression in the sacrificial layer;
depositing a moving layer material conformally over the sacrificial layer such that a portion of the moving layer material is in the depression;
depositing a support material over the moving layer material such that at least a portion of the support material is formed over the portion of the moving layer material in the depression; and
patterning the support material such that the support material is wider than and overlapping with the depression, wherein the photoresist layer serves as a mask for patterning the support material.

8. The method of claim 1, wherein the first and second developing solutions have the same composition.

9. The method of claim 1, wherein the second predetermined period of time is from about 60% to about 90% of a total of the first and second predetermined periods of time.

10. The method of claim 1, wherein the first predetermined period of time is between about 20 seconds and 90 seconds.

11. The method of claim 1, further comprising:
developing the photoresist layer a third time with a third developing solution for a third predetermined period of time after removing the second developing solution; and
removing the third developing solution after developing the photoresist layer the third time.

12. The method of claim 11, wherein the third developing solution has the same composition as at least one of the first and second developing solutions.

13. A microelectromechanical system (MEMS) comprising an array of MEMS devices, each of the devices comprising:
a stationary layer;
a moving layer overlying the stationary layer with a cavity therebetween, the moving layer being movable in the cavity between a first position and a second position, the first position being a first distance from the stationary layer, the second position being a second distance from the stationary layer, the second distance being greater than the first distance; and
a support structure configured to support the moving layer,
wherein each of the support structures across the array has a lateral dimension having a standard deviation ranging from about ±0.01 μm to about ±0.45 μm.

14. The MEMS of claim 13, wherein each of the support structures across the array has a lateral dimension having a maximum deviation from about 0.01 μm to about 0.5 μm.

15. The MEMS of claim 13, wherein the support structure comprises a post configured to space apart the moving and stationary layers.

16. The MEMS of claim 15, wherein the post comprises a post stem extending in a direction from the stationary layer to the moving layer and a post wing laterally extending from over the post stem.

17. The MEMS of claim 16, wherein the post stem has a maximum width extending substantially perpendicular to the direction, and wherein the lateral dimension comprises the maximum width of the post stem.

18. The MEMS of claim 16, wherein the post wing has a maximum width extending substantially perpendicular to the direction, and wherein the lateral dimension comprises the maximum width of the post wing.

19. The MEMS of claim 13, wherein the support structure comprises a support overlying the moving layer, the support being configured to space apart the moving and stationary layers.

20. The MEMS of claim 19, wherein the support comprises a portion extending in a direction from the stationary layer to the moving layer and a wing portion laterally extending from over the portion of the support.

21. The MEMS of claim 20, wherein the portion has a maximum width extending substantially perpendicular to the direction, and wherein the lateral dimension comprises the maximum width of the portion.

22. The MEMS of claim 20, wherein the wing portion a maximum width extending substantially perpendicular to the direction, and wherein the lateral dimension comprises the maximum width of the wing portion.

23. The MEMS of claim 13, wherein the device comprises an interferometric modulator.

24. The MEMS of claim 23, wherein the lower electrodes comprise a transparent electrode, and wherein the upper electrodes comprise a reflective electrode.

25. The MEMS of claim 13, further comprising:
a display;
a processor that is in electrical communication with the display, the processor being configured to process image data; and
a memory device in electrical communication with the processor.

26. The MEMS of claim 25, further comprising:
a first controller configured to send at least one signal to the display; and
a second controller configured to send at least a portion of the image data to the first controller.

27. The MEMS of claim 25, further comprising:
an image source module configured to send the image data to the processor.

28. The MEMS of claim 25, further comprising:
an input device configured to receive input data and to communicate the input data to the processor.
